(19) United States
(12) Patent Application Publication
(10) Pub. No.: US 2026/0159718 A1
(43) Pub. Date: Jun. 11, 2026

(54) RESIN COMPOSITION FOR FORMING PHASE-SEPARATED STRUCTURE AND METHOD FOR PRODUCING STRUCTURE INCLUDING PHASE-SEPARATED STRUCTURE

(71) Applicant: TOKYO OHKA KOGYO CO., LTD., Kawasaki-shi (JP)

(72) Inventor: Takehiro SESHIMO, Kawasaki-shi (JP)

(21) Appl. No.: 19/404,814

(22) Filed: Dec. 1, 2025

(30) Foreign Application Priority Data
Dec. 11, 2024 (JP) 2024-216919

(51) Int. Cl. C09D 153/00; C09D 7/20; G03F 7/00; G03F 7/16

(52) U.S. Cl. CPC C09D 153/00; C09D 7/20; G03F 7/0002; G03F 7/165

(57) ABSTRACT

A resin composition for forming a phase-separated structure capable of forming a coating film with a uniform thickness and forming a thick film having a well phase-separated structure while suppressing the generation of defects in the film, and a method for producing a structure including a phase-separated structure using the resin composition. The resin composition includes a block copolymer and an organic solvent including propylene glycol monomethyl ether acetate and a solvent having an ester group and a boiling point at atmospheric pressure of 225° C. or more and 275° C. or less.

This application claims priority to Japanese Patent Application No. 2024-216919, filed on Dec. 11, 2024, the entire content of which is incorporated herein by reference.

### BACKGROUND OF THE INVENTION

### Field of the Invention

The present invention relates to a resin composition for forming a phase-separated structure and to a method for producing a structure including a phase-separated structure using such a composition.

### Related Art

In recent years, following further miniaturization of a large-scale integrated circuit (LSI), a technique for processing a finer structure has been demanded. In response to such a demand, a technique has been developed to form a finer structure by utilizing a phase-separated structure formed by self-assembly of block copolymers in which mutually incompatible blocks are bonded to each other (refer, for example, to Patent Document 1).

The block copolymers separate (phase-separate) into micro-regions due to repulsion between the mutually incompatible blocks, then are subjected to heat treatment or the like to form a structure having a regular periodic structure. The periodic structure may be a cylinder (columnar), lamella (plate-like), sphere (spherical), or the like.

To use this phase-separated structure of block copolymers, it is essential that self-assembled nanostructures formed by micro-phase separation be formed only in specific regions and be arranged in a desired direction. To control a position and an orientation of these nanostructures, processes such as graphoepitaxy, which controls phase separation patterns by guiding patterns, and chemical epitaxy, which controls phase separation patterns by differences in a chemical state of a substrate, have been proposed (see, for example, Non-Patent Document 1).
Patent Document 1: Japanese Unexamined Patent Application, Publication No. 2008-36491
Non-Patent Document 1: Proc. SPIE 7637, Alternative Lithographic Technologies II, 76370G (1 Apr. 2010)

### SUMMARY OF THE INVENTION

A film having a phase-separated structure formed through self-assembly of block copolymers (hereinafter, such a film having a phase-separated structure will also be referred to as a “phase-separated film”) can be used to form patterned etch masks. In such a case, to provide an etching margin, it is sometimes necessary to form a relatively thick phase-separated film (e.g., 50 nm or more in thickness).

The phase-separated film is also required to have as few defects as possible. As used herein, the term “defects” refers to all types of defects that can be detected by observing the phase-separated pattern from directly above using a scanning electron microscope, for example. Examples of such defects include defects caused by adhesion of foreign matter or precipitates to the phase-separated pattern surface, such as adhesion of scum (resin composition residues), bubbles, or dust remaining after the formation of the phase-separated pattern; and patterning-related defects such as bridging between line patterns and clogging of patterned contact holes.

In addition, when used to form the phase-separated structure, the resin composition for forming a phase-separated structure is applied by spin coating or other methods, but must be formed into a film with uniform thickness.

The present invention has been made in view of the above circumstances, and an object thereof is to provide a resin composition for forming a phase-separated structure capable of forming a coating film with a uniform thickness and also capable of forming a thick film having a well phase-separated structure while suppressing the generation of defected in the film, and to provide a method for producing a structure including a phase-separated structure using such a resin composition.

As a result of intensive research for solving the problem, the inventors have completed the present invention based on findings that using organic solvent(S) including propylene glycol monomethyl ether acetate (S1) and a solvent (S2) having an ester group and a boiling point at atmospheric pressure of 225° C. or more and 275° C. or less can provide a solution to the problem. Specifically, the present invention provides the following aspects.

A first aspect is directed to a phase-separated structure-forming resin composition including: a block copolymer (A); and organic solvent(S), the organic solvent(S) including propylene glycol monomethyl ether acetate (S1) and a solvent (S2) having an ester group and a boiling point at atmospheric pressure of 225° C. or more and 275° C. or less.

A second aspect is a method for producing a structure having a phase-separated structure, including applying the resin composition for forming a phase-separated structure of the first aspect onto a support to form a layer containing a block copolymer, and phase-separating the layer containing the block copolymer.

The present invention provides a resin composition for forming a phase-separated structure capable of forming a coating film with a uniform thickness and also capable of forming a thick film having a well phase-separated structure while suppressing the generation of defected in the film, and provides a method for producing a structure including a phase-separated structure using such a resin composition.

### BRIEF DESCRIPTION OF THE DRAWINGS

FIG. 1 is a schematic flow diagram illustrating a method according to an embodiment for producing a structure including a phase-separated structure; and

FIG. 2 is a diagram illustrating an optional step according to an embodiment.

### DETAILED DESCRIPTION OF THE INVENTION

Hereinafter, embodiments of the present invention will be described in detail, but the present invention is not limited to the following embodiments at all, and can be carried out with appropriate modifications within the scope of the object of the present invention.

### <<Resin Composition for Forming Phase Separated-Structure>>

A first aspect is directed to a resin composition for forming a phase-separated structure including a block copolymer (A) and organic solvents(S). The organic solvents(S) include propylene glycol monomethyl ether acetate (S1) and a solvent (S2) having an ester group and a boiling point at atmospheric pressure of 225° C. or more and 275° C. or less. The composition with such features can form a uniform film, and even when forming a thick film having a phase-separated structure, it is possible to form a phase-separated structure, while suppressing the generation of defects in the film.

Although the reason for such advantageous effects remains to be clarified, the solvent (S2) tends to remain in the block copolymer-containing layer formed using the resin composition for forming a phase-separated structure according to the first aspect, and the remaining solvent (S2) may provide improved mobility for the block copolymer molecules during annealing, and thus suppress the generation of defects. In addition, propylene glycol monomethyl ether acetate (S1) in the composition can contribute to uniform film formation.

### <Block Copolymer (A)>

The block copolymer (A) is a polymer including a plurality of types of blocks linked together. There may be two types of blocks, or three of more types of blocks constituting the block copolymer (A). The plurality of types of blocks constituting the block copolymer (A) are not particularly limited so long as being a combination inducing phase separation. Preferably, the block copolymer (A) includes a combination of blocks immiscible with each other.

The block copolymer (A) preferably includes at least one selected from the group consisting of a block copolymer (A1), a block copolymer (A2), and a block copolymer (A3).

The block copolymer (A1) includes a block (A1-1) and a block (A1-2). The block (A1-1) is composed of a polymer having a repeating structure of a structural unit represented by Formula (a1) below. The block (A1-2) is composed of a polymer having a repeating structure of a structural unit represented by Formula (a3) below. The block copolymer (A2) includes a block (A2-1) and a block (A2-2). The block (A2-1) is composed of a polymer having a repeating structure of a structural unit represented by Formula (a1) below. The block (A2-2) is composed of a random copolymer having a structural unit represented by Formula (a2) below and a structural unit represented by Formula (a3) below, which are randomly arranged in the copolymer. The block copolymer (A3) includes a block (A3-1), a block (A3-2), and a block (A3-3). The block (A3-1) is composed of a polymer having a repeating structure of a structural unit represented by Formula (a1) below. The block (A3-2) is composed of a polymer having a repeating structure of a structural unit represented by Formula (a2) below. The block (A3-3) is composed of a polymer having a repeating structure of a structural unit represented by Formula (a3) below.

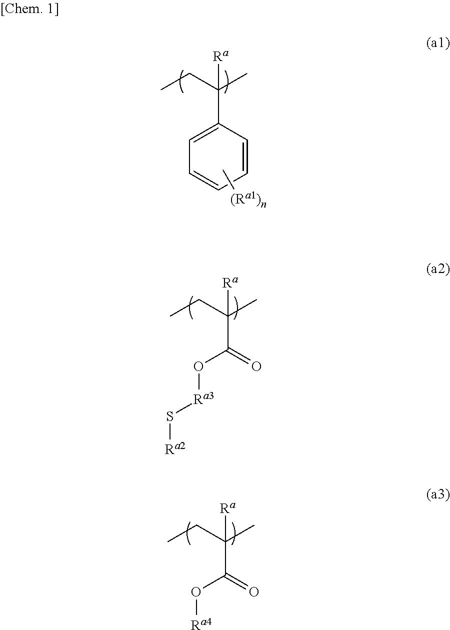

In Formula (a1), R^{a1} is an optionally substituted alkyl group, and n is an integer of 0 or more and 5 or less. In Formula (a2), R^{a2} is an alkyl group optionally substituted with a silyl group, a fluorine atom, a carboxy group, an amino group, a hydroxy group, or a phosphate group, and R^{a3} is an alkylene group optionally substituted with a hydroxy group. In Formula (a3), R^{a4} is an optionally substituted alkyl group. In Formulas (a1), (a2), and (a3), R^{a} is a hydrogen atom or a methyl group.
[Structural Unit Represented by Formula (a1)]

The alkyl group for R^{a1} preferably has 1 or more and 5 or less carbon atoms. It should be noted that the number of the carbon atoms does not include the count of carbon atoms of substituents. Examples of the alkyl group for R^{a1} include a methyl group, ethyl group, n-propyl group, isopropyl group, n-butyl group, sec-butyl group, isobutyl group, and tert-butyl group. Examples of a substituent which the alkyl group for R^{a1} may have include an alkoxy group, an alkylsilyl group, an alkylsilyloxy group, an alkoxysilyl group, and halogen atoms.

When n is an integer of 2 or more, two or more R^{a1} may be the same or different.

[Structural Unit Represented by Formula (a2)]

The alkyl group for R^{a2} preferably has 1 or more and 20 or less carbon atoms, more preferably 1 or more and 10 or less carbon atoms, and even more preferably 1 or more and 5 or less carbon atoms. The alkyl group for R^{a2} may be linear or branched. Preferably, the alkyl group for R^{a2} is linear. Examples of the alkyl group for R^{a2} include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, and an n-decyl group. In particular, the alkyl group for R^{a2} is preferably a methyl group, an ethyl group, an n-propyl group, an n-butyl group, an n-pentyl group, an n-hexyl group, an n-heptyl group, or an n-octyl group, more preferably a methyl group, an ethyl group, or an n-propyl group.

When the alkyl group for R^{a2} is substituted with a silyl group, a fluorine atom, a carboxy group, an amino group, a hydroxy group, or a phosphate group, the silyl group or other substituent is replacing a hydrogen in the alkyl group. In such a case, 1 or more and 5 or less hydrogen atoms, or 1 or more and 3 or less hydrogen atoms may have been replaced by one or more substituents. Examples of a silyl group with which the alkyl group for R^{a2} may be substituted include alkylsilyl groups such as a monoalkylsilyl group, a dialkylsilyl group, and a trialkylsilyl group. In particular, the silyl group is preferably a trialkylsilyl group. The alkyl group in the alkylsilyl group preferably has 1 or more and 5 or less carbon atoms, and more preferably 1 or more and 3 or less carbon atoms. Examples of the alkyl group in the alkylsilyl group include a methyl group, an ethyl group, an n-propyl group, an isopropyl group, an n-butyl group, an isobutyl group, a sec-butyl group, a tert-butyl group, and an n-pentyl group. In particular, the alkyl group in the alkylsilyl group is preferably a methyl group or an ethyl group, and is more preferably a methyl group.

The alkylene group for R^{a3} preferably has 2 or more carbon atoms, and more preferably 3 or more carbon atoms. The alkylene group preferably has 10 or less carbon atoms. From the viewpoint of the phase separation performance, the alkylene group more preferably has 8 or less carbon atoms, even more preferably 5 or less carbon atoms, and particularly preferably 4 or less carbon atoms. The alkylene group most preferably has 3 carbon atoms. The alkylene group for R^{a3} may be linear or branched. Preferably, the alkylene group for R^{a3} is linear.

When the alkylene group for R^{a3} may be substituted with a hydroxy group(s), the alkylene group is preferably substituted with 1 or more and 3 or less hydroxy groups, more preferably 1 or 2 hydroxy groups, and even more preferably 1 hydroxy group.

[Structural Unit Represented by Formula (a3)]

The alkyl group for R^{a4} preferably has 1 or more and 10 or less carbon atoms, and more preferably 1 or more and 5 or less carbon atoms. It should be noted that the number of carbon atoms does not include the count of carbon atoms of the substituents. Examples of the alkyl group for R^{a4} include a methyl group, an ethyl group, an n-propyl group, an isopropyl group, an n-butyl group, an n-pentyl group, an n-hexyl group, an n-heptyl group, an n-octyl group, an n-nonyl group, and an n-decyl group. In particular, the alkyl group for R^{a4} is

preferably methyl.

[Block Copolymer (A1)]

In the block copolymer (A1), a ratio of the number of moles of the structural unit of the block (A1-1) to the sum of the number of moles of the structural unit of the block (A1-1) and the number of moles of the structural unit of the block (A1-2) is preferably 20 mol % or more and 80 mol % or less, more preferably 30 mol % or more and 70 mol % or less, and even more preferably 40 mol % or more and 60 mol % or less.

In the block copolymer (A1), a ratio of the number of moles of the structural unit of the block (A1-2) to the sum of the number of moles of the structural unit of the block (A1-1) and the number of moles of the structural unit of the block (A1-2) is preferably 20 mol % or more and 80 mol % or less, more preferably 30 mol % or more and 70 mol % or less, and even more preferably 40 mol % or more and 60 mol % or less.

The block copolymer (A1) may further include any other block in addition to the blocks (A1-1) and (A1-2). In a preferred mode, the block copolymer (A1) is a diblock copolymer composed of the blocks (A1-1) and (A1-2).

### [Block Copolymer (A2)]

In the block copolymer (A2), a ratio of the number of moles of the structural unit of the block (A2-1) to the sum of the number of moles of the structural unit of the block (A2-1) and the number of moles of the structural unit of the block (A2-2) is preferably 20 mol % or more and 80 mol % or less, more preferably 30 mol % or more and 70 mol % or less, and even more preferably 40 mol % or more and 60 mol % or less.

In the block copolymer (A2), a ratio of the number of moles of the structural unit of the block (A2-2) to the sum of the number of moles of the structural unit of the block (A2-1) and the number of moles of the structural unit of the block (A2-2) is preferably 20 mol % or more and 80 mol % or less, more preferably 30 mol % or more and 70 mol % or less, and even more preferably 40 mol % or more and 60 mol % or less.

In the block (A2-2), a ratio of the number of moles of the structural unit of Formula (a2) to the sum of the number of moles of the structural units of Formula (a2) and the number of moles of the structural unit of Formula (a3) is preferably 90 mol % or less, more preferably 30 mol % or less, and even more preferably 1 mol % or more and 10 mol % or less.

The block copolymer (A2) may further include any other block in addition to the blocks (A2-1) and (A2-2). In a preferred mode, the block copolymer (A2) is a diblock copolymer composed of the blocks (A2-1) and (A2-2).

### [Block Copolymer (A3)]

In the block copolymer (A3), a ratio of the number of moles of the structural unit of the block (A3-1) to the sum of the number of moles of the structural unit of the block (A3-1), the number of moles of the structural unit of the block (A3-2), and the number of moles of the structural unit of the block (A3-3) is preferably 20 mol % or more and 80 mol % or less, more preferably 30 mol % or more and 70 mol % or less, and even more preferably 40 mol % or more and 60 mol % or less.

In the block copolymer (A3), a ratio of the number of moles of the structural unit of the block (A3-2) to the sum of the number of moles of the structural unit of the block (A3-1), the number of moles of the structural unit of the block (A3-2), and the number of moles of the structural unit of the block (A3-3) is preferably 0.5 mol % or more and 8 mol % or less, more preferably 1 mol % or more and 7 mol % or less, and even more preferably 1.5 mol % or more and 6 mol % or less.

In the block copolymer (A3), a ratio of the number of moles of the structural unit of the block (A3-3) to the sum of the number of moles of the structural unit of the block (A3-1), the number of moles of the structural unit of the block (A3-2), and the number of moles of the structural unit of the block (A3-3) is preferably 10 mol % or more and 70 mol % or less, more preferably 15 mol % or more and 65 mol % or less, and even more preferably 20 mol % or more and 60 mol % or less.

The block copolymer (A3) preferably includes the blocks (A3-1), (A3-2), and (A3-3) in that order. Alternatively, the block copolymer (A3) preferably includes the blocks (A3-1), (A3-3), and (A3-2) in that order.

The block copolymer (A3) may further include any other block in addition to the blocks (A3-1), (A3-2), and (A3-3). In a preferred mode, the block copolymer (A3) is a triblock copolymer composed of the blocks (A3-1), (A3-2), and (A3-3).

The number average molecular weight (Mn) of the block copolymer (A) is not particularly limited. The number average molecular weight (Mn) of the block copolymer (A) is preferably 10,000 or more and 300,000 or less, more preferably 20,000 or more and 200,000 or less, and even more preferably 30,000 or more and 100,000 or less. The block copolymer (A) preferably has a molecular weight dispersity (Mw/Mn) of 1.0 or more and 1.5 or less, more preferably 1.0 or more and 1.4 or less, and even more preferably 1.0 or more and 1.3 or less. In the present specification, the “number average molecular weight” (Mn) and the “weight average molecular weight” (Mw) mean a number average molecular weight and a weight average molecular weight, respectively, in terms of standard polystyrene determined by gel permeation chromatography (GPC) measurement, unless otherwise specified. When a value of Mn or Mw is given a unit (gmol-1), the value represents a molar mass.

### <Organic Solvent(S)>

The organic solvent(S) includes propylene glycol monomethyl ether acetate (S1) and a solvent (S2) having an ester group and a boiling point at atmospheric pressure of 225° C. or more and 275° C. or less.

### [Solvent (S2)]

The boiling point at atmospheric pressure of the solvent (S2) is 225° C. or more and 275° C. or less, preferably 227° C. or more and 273° C. or less, and more preferably 229° C. or more and 271° C. or less. When a boiling point at atmospheric pressure of 225° C. or more, the occurrence of defects can be suppressed. When a boiling point at atmospheric pressure of 275° C. or less can contribute to uniform film formation.

The solvent (S2) may have any number of ester groups. The solvent (S2) preferably has one or more and three or less ester groups, and more preferably one or two ester groups.

The solvent (S2) is preferably a compound represented by Formula (s2-1) below.

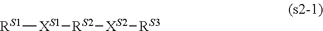

In Formula (s2-1), R^{S1} is a hydrogen atom or an optionally substituted alkyl group, R^{S2} is a single bond or an optionally substituted alkylene group, R^{S3} is an optionally substituted alkyl group, X^{S1} is a single bond or an ester group, and X^{S2} is an ester group.

The alkyl group for R^{S1} or R^{S3} preferably has 1 or more and 10 or less carbon atoms, more preferably 1 or more and 5 or less carbon atoms, and even more preferably 1 or more and 3 or less carbon atoms. It should be noted that the number of the carbon atoms does not include the count of carbon atoms of the substituents. The alkyl group for R^{S1} or R^{S3} may be linear or branched. Preferably, the alkyl group for R^{S1} or R^{S3} is linear. Examples of the alkyl group for R^{S1} or R^{S3} include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, and an n-decyl group. In particular, the alkyl group for R^{S1} or R^{S3} is preferably a methyl group, an ethyl group, an n-propyl group, an n-butyl group, or an n-pentyl group, more preferably a methyl group or an ethyl group.

Examples of a substituent which the alkyl group for R^{S1} or R^{S3} may have include a silyl group, a fluorine atom, a fluoroalkyl group, an acyl group, and an alkoxy group. Examples of the silyl group include trialkylsilyl groups such as a trimethylsilyl group, a triethylsilyl group. Examples of the fluoroalkyl group include a trifluoromethyl group. Examples of the acyl group include an acetyl group. Examples of the alkoxy group include a methoxy group and an ethoxy group.

The alkylene group for R^{S2} preferably has 1 or more and 30 or less carbon atoms, more preferably 2 or more and 20 or less carbon atoms, and even more preferably 3 or more and 10 or less carbon atoms. The alkylene group for R^{S2} may be linear or branched. Preferably, the alkylene group for R^{S2} is linear. Examples of the alkylene group for R^{S2} include a methylene group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, and a decane-1,10-diyl group. Examples of a substituent which the alkylene group for R^{S2} may have include those listed above for the substituent which the alkyl group for R^{S1} or R^{S3} may have.

The ester group for X^{S1} or X^{S2} may have any orientation. The orientation of the ester group for X^{S1} or X^{S2} may be —C(═O)—O— or —O—C(═O)—.

Examples of the solvent (S2) include ethyl decanoate (boiling point 243° C.), ethyl undecanoate (boiling point 260° C.), dimethyl suberate (boiling point 270° C.), 1,4-diacetoxybutane (boiling point 230° C.), and dibutyl oxalate (boiling point 246° C.). These solvents may be used alone, or two or more of these solvents may be used in combination.

### [Solvent (S3)]

The organic solvent(S) may further include a solvent (S3) in addition to propylene glycol monomethyl ether acetate (S1) and the solvent (S2).

Examples of the solvent (S3) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; monoacetates of polyhydric alcohols such as ethylene glycol monoacetate, diethylene glycol monoacetate, and propylene glycol monoacetate; polyhydric alcohol derivatives, such as compounds having an ether bond such as monoalkyl ethers of the polyhydric alcohols, monoalkyl ethers of monoacetates of the polyhydric alcohols, monophenyl ethers of the polyhydric alcohols, and monophenyl ethers monoacetates of the polyhydric alcohols (Examples of monoalkyl ethers include monomethyl ether, monoethyl ether, monopropyl ether, and monobutyl ether, or the like.) [among these, propylene glycol monomethyl ether (PGME) is preferred]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, ethyl ethoxypropionate, and esters other than the derivatives of the foregoing polyhydric alcohols; and aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, and mesitylene. These solvents may be used alone, or two or more of these solvents may be used in combination.

The concentration of the organic solvent(S) in the resin composition for forming a phase-separated structure may be appropriately set depending on the target coating thickness such that it has a concentration suitable for application. In general, the resin composition for forming a phase-separated structure contains the organic solvent(S) at a concentration that allows it to have a solids content in the range of 0.2% by mass % or more and 70% by mass or less, preferably 0.2% by mass or more and 50% by mass or less.

The ratio of the mass of propylene glycol monomethyl ether acetate (S1) to the total mass of the organic solvent(S) is preferably 40% by mass or more and 95% by mass or less, more preferably 45% by mass or more and 90% by mass or less, even more preferably 50% by mass or more and 85% by mass or less. Within this numerical range, desired effects can be easily obtained.

The ratio of the mass of the solvent (S2) to the total mass of the organic solvent(S) is preferably 58 by mass or more and 60% by mass or less, more preferably 10% by mass or more and 55% by mass or less, and even more preferably 15% by mass or more and 50% by mass or less. Within this numerical range, desired effects can be easily obtained.

The ratio of the mass of the solvent (S2) to the total mass of propylene glycol monomethyl ether acetate (S1) and the solvent (S2) is preferably 5% by mass or more and 60% by mass or less, more preferably 10% by mass or more and 55% by mass or less, and even more preferably 15% by mass or more and 50% by mass or less. When the content is 5 mass % or more, the occurrence of defects is easily suppressed. When the content is 60 mass % or less, a uniform film is easily formed.

For ease of achieving the desired advantageous effects, the ratio of the total mass of propylene glycol monomethyl ether acetate (S1) and the solvent (S2) to the total mass of the organic solvents(S) is preferably 50% by mass or more, more preferably 70% by mass or more, even more preferably 80% by mass or more, and particularly preferably 90% by mass or more.

### <Other Ingredients>

The resin composition for forming a phase-separated structure may contain an additional component besides the block copolymer (A) and the organic solvents(S). Examples of the other ingredients include other resins such as a homopolymer, a surfactant, a dissolution inhibitor, a plasticizer, a stabilizer, a colorant, an anti-halation agent, a dye, a sensitizer, an alkali booster, and a basic compound.

### <<Manufacturing Method for Structure Including Phase-Separated Structure>>

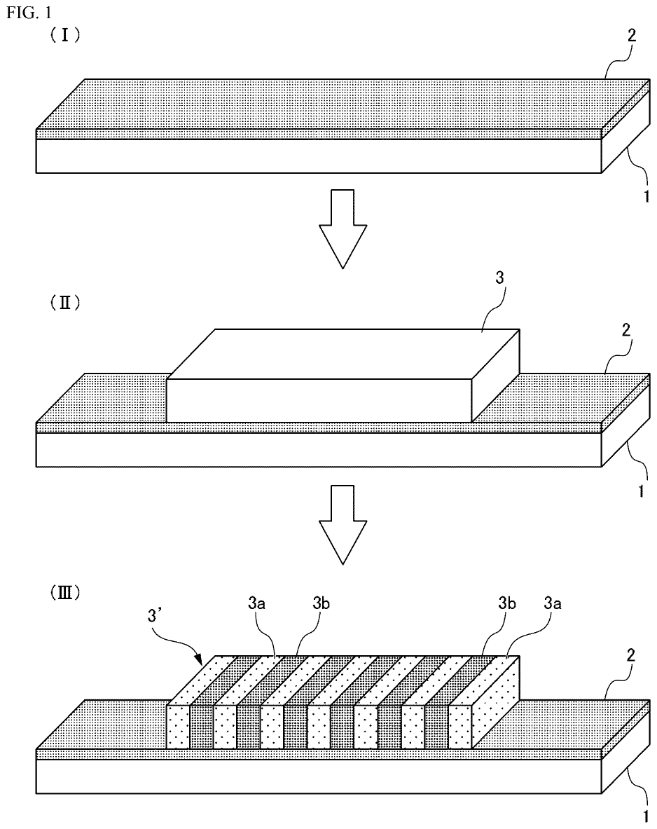

A method for producing a structure including a phase-separated structure includes applying a resin composition for forming a phase-separated structure onto a support to form a layer including a block copolymer (hereinafter, referred to as “step (i)”), and phase-separating the layer including the block copolymer (hereinafter, referred to as “step (ii)”). Hereinafter, a method for producing a structure including such a phase-separated structure will be specifically described with reference to FIG. 1. However, the method for producing a structure including the phase-separated structure is not limited to the embodiment specifically shown in FIG. 1.

FIG. 1 illustrates one example embodiment of the method for producing a structure including a phase-separated structure. In the embodiment shown in FIG. 1, first, a support 1 is coated with a primer to form a primer layer 2 (FIG. 1(I)). Next, the resin composition for forming a phase-separated structure is applied on the primer layer 2 to form a layer (BCP layer) 3 containing a block copolymer (FIG. 1 (II); this concludes step (i)). Next, the BCP layer 3 is phase-separated into a phase 3a and a phase 3b by heating and annealing (FIG. 1 (III); step (ii)). According to the production method of the embodiment, that is, the production method including the step (i) and the step (ii), a structure 3′ including the phase-separated structure is produced on the support 1 on which the primer layer 2 is formed.

<Step (i)>

The step (i) includes applying the resin composition for forming a phase-separated structure onto the support 1 to form the BCP layer 3. In an embodiment shown in FIG. 1, a primer is first applied onto the support 1 to form a primer layer 2. The primer layer 2 on the support 1 can provide a good hydrophilic-hydrophobic balance between the surface of the support 1 and the layer 3 including the block copolymer (BCP layer). Specifically, when the primer layer 2 includes a resin component including the same repeating unit as constituting any of the blocks of the block copolymer, the phase including the corresponding block of the BCP layer 3 can have high adhesion to the support 1. In such a case, when the BCP layer 3 undergoes phase separation, it can easily form a phase-separated structure vertically oriented with respect to the surface of the support 1.

### Primers:

As a primer, a resin composition can be used. The resin composition for primers can be appropriately selected from conventionally known resin compositions for use in forming a thin film depending upon the type of blocks constituting the block copolymer. The resin composition for primers may be, for example, a thermally polymerizable resin composition or a photosensitive resin composition, such as a positive resist composition or a negative resist composition. In addition, a non-polymerizable film formed by using a compound as a surface treatment agent and applying the compound may be used as the primer layer. For example, a siloxane-based organic monomolecular film formed of phenethyltrichlorosilane, octadecyltrichlorosilane, hexamethyldisilazane, or the like as a surface treatment agent can also be suitably used as the primer layer.

Examples of such resin compositions include a resin composition containing a resin having all of the structural units constituting each of the blocks constituting the block copolymer, and a resin composition containing a resin having structural units that have high affinity with all of the blocks constituting the block copolymer. As the resin composition for primers, for example, a composition containing a resin having both styrene and methyl methacrylate as structural units, or a compound or a composition including both a site having high affinity for styrene, such as an aromatic ring, and a site having high affinity with methyl methacrylate (a functional group having high polarity or the like) is preferably used. Examples of the resin having both styrene and methyl methacrylate as structural units include random copolymers of styrene and methyl methacrylate, alternating polymers of styrene and methyl methacrylate (polymers in which each monomer is copolymerized alternately), and the like. Examples of the composition including both a site having high affinity with styrene and a site having high affinity with methyl methacrylate include a composition containing a resin obtained by polymerizing, as a monomer, a monomer having at least an aromatic ring and a monomer having a polar functional group. Examples of the monomer having an aromatic ring include monomers having an aryl group in which one hydrogen atom is removed from a ring of the aromatic hydrocarbon, such as a phenyl group, a biphenyl group, a fluorenyl group, a naphthyl group, an anthryl group, or a phenanthryl group, or monomers having a heteroaryl group in which some of carbon atoms constituting the ring of these groups is/are replaced with a heteroatom(s) such as an oxygen atom, a sulfur atom, or a nitrogen atom. Examples of the monomer having a highly polar functional group include monomers having a trimethoxysilyl group, a trichlorosilyl group, an epoxy group, a glycidyl group, a carboxy group, a hydroxy group, a cyano group, a hydroxyalkyl group in which some of the hydrogen atoms of the alkyl group is/are substituted with a hydroxy group(s), and the like. Other examples of the compound having both a site having a high affinity with styrene and a site having a high affinity with methyl methacrylate include a compound having both an aryl group and a polar functional group such as phenethyltrichlorosilane and a compound having both an alkyl group and a polar functional group such as an alkylsilane compound.

The resin composition for primers can be produced by dissolving any one of the above-described resins in a solvent. As such a solvent, any solvent may be used as long as it dissolves each component to be used and can form a uniform solution, and examples thereof include the same solvents as those exemplified in the description of the resin compositions for forming a phase-separated structure.

The type of the support 1 is not particularly limited as long as the resin composition can be applied on the surface thereof. Examples of substrates include a substrate made of an inorganic material such as silicon, a metal (copper, chromium, iron, aluminum, or the like), glass, titanium oxide, silica, or mica; a substrate made of an oxide such as SiO₂; a substrate made of a nitride such as SiN; a substrate made of an oxynitride such as SiON; a substrate made of an organic material such as an acrylic resin, a polystyrene, a cellulose, a cellulose acetate, and a phenol resin. Among these, a silicon substrate (Si substrate) or a metal substrate is preferable, a Si substrate or a copper substrate (Cu substrate) is more preferable, and a Si substrate is particularly preferable. The size and shape of the support 1 are not particularly limited. The support 1 does not necessarily have a smooth surface, and substrates having various shapes can be appropriately selected. Examples of the substrate include a substrate having a curved surface, a flat plate having an uneven surface, and a substrate having a flaky shape.

An inorganic and/or organic film may be provided on the surface of the support 1. Examples of the inorganic film include an inorganic antireflection film (inorganic BARC). Examples of the organic film include an organic antireflection film (organic BARC). An inorganic film can be formed, for example, by applying an inorganic antireflection film composition such as a silicon-based material onto a support and baking the composition. An organic film can be formed, for example, by applying a material for forming the organic film, in which a resin component or the like to constitute the film is dissolved in an organic solvent, onto a substrate by a spinner or the like, and baking the material under heating conditions of preferably 200° C. or more and 300° C. or less and preferably 30 seconds or more and 300 seconds or less, and more preferably 60 seconds or more and 180 seconds or less. This material for forming an organic film does not necessarily require sensitivity to light or electron beams, unlike a resist film, and may or may not have sensitivity. Specifically, a resist or a resin generally used in the production of semiconductor elements or liquid crystal display elements can be used. A raw material for forming organic films is preferably a material capable of forming an organic film that can be etched, particularly dry etched, so that an organic film pattern can be formed by etching an organic film using a pattern made of a block copolymer formed by processing the BCP layer 3 and transferring the pattern to the organic film. Among them, a material that forms an organic film that is etchable by oxygen plasma is preferable. Such a material for forming an organic film may be a material conventionally used for forming an organic film such as organic BARC. Examples thereof include ARC series manufactured by Nissan Chemical Corporation, AR series manufactured by Rohm & Haas, SWK series manufactured by Tokyo Ohka Kogyo, and the like.

A method for forming the primer layer 2 by applying a primer on the support 1 is not particularly limited, and the primer layer can be formed by a conventionally known method. For example, the primer layer 2 can be formed by applying the primer onto the support 1 by a conventionally known method such as spin coating or using a spinner to form a coating film, and drying the coating film. A drying method of the coating film may be any method as long as the solvent contained in the primer can be volatilized, and examples thereof include a baking method. At this time, a baking temperature is preferably 80° C. or more and 300° C. or less, more preferably 180° C. or more and 270° C. or less, and still more preferably 220° C. or more and 250° C. or less. Baking time is preferably 30 seconds or more and 600 seconds or less, and more preferably 60 seconds or more and 600 seconds or less. The primer layer 2 resulting from the drying of the coating film preferably has a thickness of about 5 nm or more and about 100 nm or less.

Before the primer layer 2 is formed on the support 1, the surface of the support 1 may be cleaned in advance. By cleaning the surface of the support 1, coatability of the primer is improved. As a cleaning treatment method, a conventionally known method can be used, and examples thereof include an oxygen plasma treatment, an ozone oxidation treatment, an acid alkali treatment, and a chemical modification treatment.

After the primer layer 2 is formed, the primer layer 2 may be rinsed with a rinse liquid such as a solvent as necessary. Since an uncrosslinked portion, etc. in the primer layer 2 is removed by the rinsing, affinity with at least one block constituting the block copolymer is improved, and a phase-separated structure composed of a cylinder structure oriented in a direction perpendicular to the surface of the support 1 is easily formed. Note that the rinse solution may be any solution as long as it can dissolve the uncrosslinked portion, and a solvent such as propylene glycol monomethyl ether acetate (PGMEA), propylene glycol monomethyl ether (PGME), or ethyl lactate (EL), a commercially available thinner solution, or the like can be used. After the cleaning, post-baking may be performed to volatilize the rinse liquid. The temperature condition of this post-baking is preferably 80° C. or more and 300° C. or less, and more preferably 100° C. or more and 270° C. or less. The baking time is preferably 30 seconds or more and 500 seconds or less, and more preferably 60 seconds or more and 240 seconds or less. The thickness of the primer layer 2 after the post-baking is preferably about 1 nm or more and 10 nm or less, and more preferably about 2 nm or more and 7 nm or less.

Next, a layer 3 (BCP layer) including a block copolymer is formed on the primer layer 2. A method for forming the BCP layer 3 on the primer layer 2 is not particularly limited, and examples thereof include a method in which the resin composition for forming a phase-separated structure of the above-described embodiment is applied on the primer layer 2 by a conventionally known method such as spin coating or using a spinner to form a coating film, followed by drying.

A thickness of the BCP layer 3 may be any thickness as long as it is sufficient to cause phase separation, and is preferably 10 nm or more and 100 nm or less, and more preferably 20 nm or more and 80 nm or less, in consideration of the type of the support 1, the structure period size of the phase-separated structure to be formed, the uniformity of the nanostructure, or the like. Thickness is more preferably 30 nm to 80 nm, particularly preferably 40 nm to 80 nm, and most preferably 50 nm to 80 nm from the viewpoint of easily suppressing the generation of defected in the phase separation film even when forming a thick phase separation film.

<Step (ii)>

In the step (ii), the BCP layer 3 formed on the support 1 is phase-separated. By heating and annealing the support 1 after the step (i), a phase-separated structure in which at least part of the surface of the support 1 is exposed is formed by selective removal of the block copolymer. That is, a structure 3′ including a phase-separated structure where the BCP layer has separated into the phase 3a and the phase 3b is produced on the support 1. The temperature condition of the annealing treatment is preferably equal to or higher than the glass transition temperature of the block copolymer used and lower than the thermal decomposition temperature, and for example, when the block copolymer is a polystyrene-polymethyl methacrylate (PS-PMMA) block copolymer (mass average molecular weight: 5,000 or more and 100,000 or less), the temperature is preferably 180° C. or higher and 270° C. or lower. The heating time is preferably 30 seconds or more and 3, 600 seconds or less. The annealing treatment is preferably performed in a gas having low reactivity such as nitrogen.

### <Optional Steps>

A method for producing the structure including a phase-separated structure is not limited to the above-described embodiment, and may include a step (optional step) other than the steps (i) and (ii).

Examples of such an optional step include selectively removing, from the BCP layer 3, a phase including at least one of the blocks in the block copolymer (hereinafter referred to as “step (iii)”) and forming a guide pattern (guide pattern formation step).

Regarding Step (iii)

Step (iii) includes selectively removes a phase including at least one of the blocks of the block copolymer in the BCP layer formed on the primer layer 2. Step (iii) results in the formation of a fine pattern (polymer nanostructure).

The selective removal of a phase including a specific block may be performed by a method including subjecting the BCP layer to oxygen plasma treatment, hydrogen plasma treatment, or any other suitable method. For example, allowing the BCP layer including the block copolymer (A1) to undergo phase separation is followed by subjecting the BCP layer to oxygen plasma treatment or hydrogen plasma treatment to selectively remove the block (A1-2) phase without selectively removing the block (A1-1) phase.

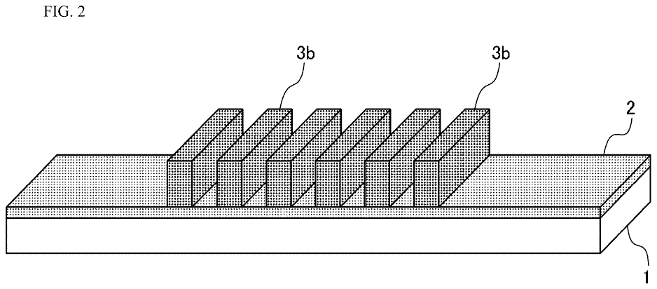

FIG. 2 illustrates one example embodiment of the step (iii). In the embodiment shown in FIG. 2, the structure 3′ produced on the support 1 in the step (ii) is subjected to oxygen plasma treatment to selectively remove the phase 3a, thereby forming a pattern (polymer nanostructure) composed of separated phases 3b. In this case, the phase 3b is a phase composed of the first block, and the phase 3a is a phase composed of the second block.

Although the support 1 on which the pattern is formed by the phase separation of the BCP layer 3 composed of the block copolymer as described above may be used as it is, the shape of the pattern (polymer nanostructure) on the support 1 may be changed by further heating. The heating temperature is preferably equal to or higher than the glass transition temperature of the block copolymer used and lower than the thermal decomposition temperature. The heating is preferably performed in a gas having low reactivity such as nitrogen.

### Regarding Guide Pattern Forming Step

The method for producing a structure including a phase-separated structure may include a step of providing a guide pattern on the primer layer (a guide pattern forming step) between the above-described step (i) and step (ii). This allows an array structure of the phase-separated structure to be controlled. For example, even if the block copolymer is the one that forms a random fingerprint-shaped phase-separated structure when a guide pattern is not provided, by providing a groove structure of a resist film on the surface of the primer layer, a phase-separated structure oriented along the groove can be obtained. Based on such a principle, a guide pattern may be provided on the primer layer 2. Further, in the case where a surface of a guide pattern has affinity with any one of the blocks constituting the above-mentioned block copolymer, a phase-separated structure having a cylinder structure oriented in a direction perpendicular to the surface of the support is likely to be formed.

The guide pattern can be formed using, for example, a resist composition. For a resist composition for forming a guide pattern, generally, a resist composition having affinity with any of the blocks constituting the block copolymer can be appropriately selected from a composition to be used for forming a resist pattern or a modified product thereof. The resist composition may be either a positive-type resist composition that forms a positive-type pattern, where an exposed area of the resist film is dissolved and removed or a negative-type resist composition that forms a negative-type pattern, where a non-exposed area of a resist film is dissolved and removed, but a negative-type resist composition is preferred. The negative-type resist composition is preferably a resist composition that contains, for example, an acid generating agent and a substrate component having a solubility that decreases in an organic solvent-containing developing solution under action of an acid, and the substrate component contains a resin component having a structural unit that degrades under action of an acid to have an increased polarity. After the BCP composition is poured onto a primer layer on which a guide pattern has been formed, an annealing treatment is performed to cause phase separation. Therefore, as a resist composition capable of forming a guide pattern, a composition capable of forming a resist film having excellent solvent resistance and heat resistance is preferable.

As described above, the present invention provides aspects (1) to (8) below.
(1) A resin composition for forming a phase-separated structure includes: a block copolymer (A); and organic solvent(S), the organic solvent(S) including propylene glycol monomethyl ether acetate (S1) and a solvent (S2) having an ester group and a boiling point at atmospheric pressure of 225° C. or more and 275° C. or less.
(2) The resin composition for forming a phase-separated structure as described in (1), wherein a ratio of the mass of the solvent (S2) to total mass of the propylene glycol monomethyl ether acetate (S1) and the solvent (S2) is 5% by mass or more and 60% by mass or less.
(3) The resin composition for forming a phase-separated structure as described in (1) or (2), wherein a ratio of a sum of mass of the propylene glycol monomethyl ether acetate (S1) and mass of the solvent (S2) to total mass of the solvents(S) of 90% by mass or more.
(4) The resin composition for forming a phase-separated structure as described in any one of (1) to (3), the solvent (S2) is a compound represented by Formula (s2-1):

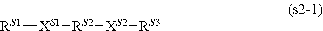

in which R^{S1} is a hydrogen atom or an optionally substituted alkyl group, R^{S1} is a single bond or an optionally substituted alkylene group, R^{S1} 3 is an optionally substituted alkyl group, X^{S1} is a single bond or an ester group, and X^{S1} is an ester group.
(5) The resin composition for forming a phase-separated structure as described in any one of (1) to (4), the block copolymer (A) includes at least one selected from the group consisting of a block copolymer (A1), a block copolymer (A2), and a block copolymer (A3), the block copolymer (A1) includes a block (A1-1) and a block (A1-2), the block (A1-1) composed of a polymer having a repeating structure of a structural unit represented by Formula (a1) below, and the block (A1-2) is composed of a polymer having a repeating structure of a structural unit represented by Formula (a3) below, the block copolymer (A2) includes a block (A2-1) and a block (A2-2), the block (A2-1) is composed of a polymer having a repeating structure of a structural unit represented by Formula (a1) below, and the block (A2-2) is composed of a random copolymer having a structure in which a structural unit represented by Formula (a2) below and a structural unit represented by Formula (a3) below are randomly arranged, the block copolymer (A3) includes a block (A3-1), a block (A3-2), and a block (A3-3), the block (A3-1) is composed of a polymer having a repeating structure of a structural unit represented by Formula (a1) below, the block (A3-2) is composed of a polymer having a repeating structure of a structural unit represented by Formula (a2) below, and the block (A3-3) is composed of a polymer having a repeating structure of a structural unit represented by Formula (a3) below,

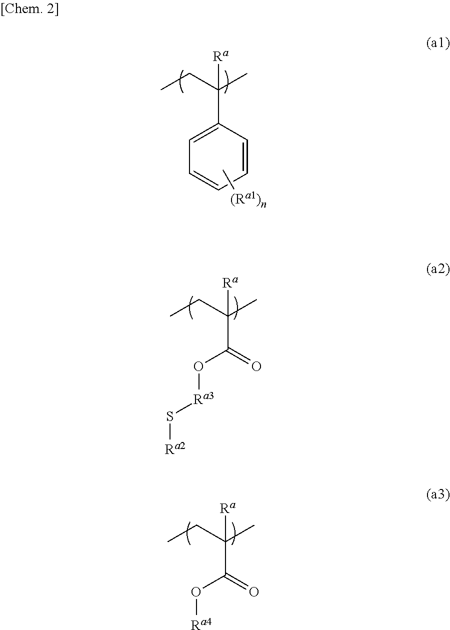

in Formula (a1), R^{a1} is an optionally substituted alkyl group, and n is an integer of 0 or more and 5 or less, in Formula (a2), R^{a2} is an alkyl group optionally substituted with a silyl group, a fluorine atom, a carboxy group, an amino group, a hydroxy group, or a phosphate group, and R^{a3} is an alkylene group optionally substituted with a hydroxy group, in Formula (a3), R^{a4} is an optionally substituted alkyl group, and in Formulas (a1), (a2), and (a3), R^{a} is a hydrogen atom or a methyl group.
(6) A method for producing a structure having a phase-separated structure, the method comprising:
applying the resin composition for forming a phase-separated structure as described in any one of (1) to (7) on a support to form a layer containing a block copolymer, and phase separating the layer comprising the block copolymer.

### Examples

Hereinafter, the present invention will be described in more detail with reference to examples; however, these examples are not intended to limit the present invention.

Block copolymers and organic solvents for use in the examples and comparative examples are shown below.

### [Block Copolymers]

BCP-1: A block copolymer represented by the formula below and having a block composed of polystyrene and a block composed of polymethyl methacrylate (Mn 60,000, x:y=48:52 (mol %))

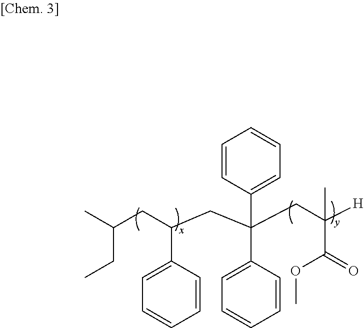

BCP-2: A block copolymer represented by the formula below and having a block composed of polystyrene and a block composed of a random copolymer of 2-hydroxy-3-(ethylsulfanyl) propyl methacrylate and methyl methacrylate (Mn 56,000, x:y:z=45:3:52 (mol %))

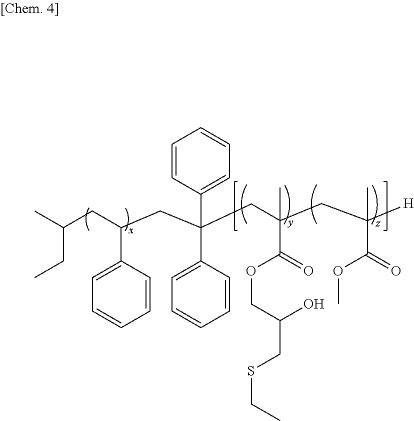

BCP-3: A block copolymer represented by the formula below and having a block composed of polystyrene, a block composed of poly(2-hydroxy-3-(ethylsulfanyl) propyl methacrylate), and a block composed of polymethyl methacrylate (Mn 56,000, x:y:z=47:3:50 (mol %))

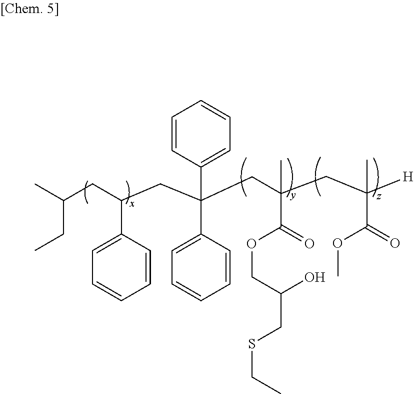

### [Organic Solvents]

(S1)-1: Propylene glycol monomethyl ether acetate (boiling point 146° C.)
(S2)-1: Ethyl decanoate (boiling point 243° C.)

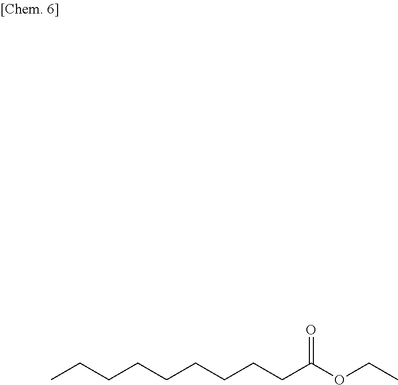

(S2)-2: Dimethyl suberate (boiling point 270° C.)

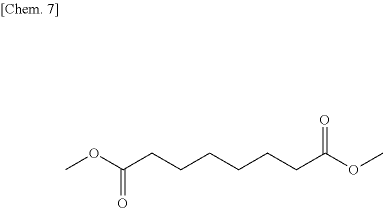

(S2)-3: 1,4-Diacetoxybutane (boiling point 230° C.)

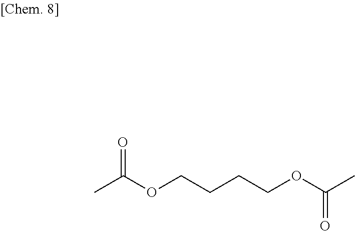

(S3)-1:3-Methoxybutyl acetate (boiling point 172° C.)
(S3)-2: γ-Butyrolactone (boiling point 204° C.)
(S3)-3: Triethylene glycol butyl methyl ether (boiling point: 261° C.)

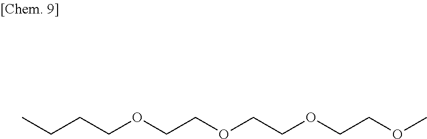

(S3)-4: Heptyl enanthate (boiling point 277° C.)

### <Preparation of Resin Compositions for Forming Phase-Separated Structure>

100 parts by mass of the block copolymer (BCP) of the type shown in Tables 1 to 3 and the organic solvents of the types and amounts (parts by mass) shown in Tables 1 to 3 were mixed and dissolved to prepare a resin composition for forming a phase-separated structure of each Example.

### <Evaluation of Film-Forming Performance>

The resin composition for forming a phase-separated structure for each example was applied onto an 8-inch silicon wafer using a spinner and dried by baking at 90° C. for one minute to form a 50 nm-thick layer including the block copolymer (BCP layer). As a result of visual observation, the BCP layer was rated “A” when it uniformly covered the entirety of the wafer, and rated “B” when it was found to be uneven. The results are shown in the “Film-forming performance” column of Tables 1 to 3.

### <Production of Structure Including Phase Separated Structure>

A guide pattern was formed using a resist composition. A process including steps (i) and (ii) shown below was then performed using the resin composition for forming a phase-separated structure for each example to form a structure including a phase-separated structure. It should be noted that the compositions rated “B” for film-forming performance were not subjected to the formation of a structure including a phase-separated structure or the defect evaluation, due to a uniform film formation not being possible.

### (Formation of Guide Pattern)

An organic anti-reflective coating composition (ARC-29A (trade name) manufactured by Brewer Science) was applied onto a 12-inch silicon wafer substrate using a spinner, and dried by baking on a hot plate at 205° C. for 60 seconds to form an 89 nm-thick organic anti-reflective film. A solution of a cross-linked neutral coating composition was spin-coated on the organic anti-reflective film, and then heated at 250° C. for 600 seconds. As a result, a 6 nm-thick thin film of the cross-linked neutral coating composition was formed on the surface of the substrate. A guide pattern-forming resist film composition was applied onto the thin film using a spinner, and dried by pre-baking (PAB) on a hot plate to form a 90 nm-thick guide pattern-forming resist film. The resist film was selectively exposed through a patterned mask to an ArF excimer laser beam (193 nm) from an ArF exposure system (XT-1900Gi (trade name) manufactured by ASML). After the exposure, the resist film was subjected to heat treatment (PEB), developed with butyl acetate, and shaken off to dry. The process was followed by post-baking at 100° C. for 1 minute, and then at 200° C. for 5 minutes to form a guide pattern with a space dimension four times the d value of the block copolymer used (d spacing determined by small-angle X-ray scattering).

### (Step (i))

The resin composition for forming a phase-separated structure for each example was spin-coated on the substrate with the guide pattern and then pre-baked at 90° C. for 60 seconds under a nitrogen atmosphere to form a 50 nm-thick layer including the block copolymer (BCP layer).

(Step (ii))

The BCP layer formed on the substrate was annealed at 200° C. for 5 minutes under a nitrogen atmosphere to form a phase-separated structure.

### <Evaluation of Pattern Defects>

For the pattern after process (ii), 10 sheets were observed from above at a magnification of 100,000 times by a length-measuring SEM (scanning electron microscope, trade name: CG6300, manufactured by Hitachi High-Technologies Corporation), and the number of defects was counted. The counting results were used to evaluate pattern defects based on the criteria below. The results are shown in the “Defects” column of Tables 1 to 3.

### (Evaluation Criteria)

A: The total number of defects less than 5
B: The total number of defects 5 or more and less than 10
C: The total number of defects is 10 or more

TABLE 1

| | (A) | (S1) | | (S2) | | (S3) | | Film-forming | |
|---|---|---|---|---|---|---|---|---|---|
| | Type | Type | Amount | Type | Amount | Type | Amount | performance | Defects |
| Ex. 1 | BCP-1 | (S1)-1 | 5204 | (S2)-1 | 578 | — | — | A | B |
| Ex. 2 | BCP-1 | (S1)-1 | 4626 | (S2)-1 | 1156 | — | — | A | A |
| Ex. 3 | BCP-1 | (S1)-1 | 4048 | (S2)-1 | 1735 | — | — | A | A |
| Ex. 4 | BCP-1 | (S1)-1 | 3469 | (S2)-1 | 2313 | — | — | A | A |
| Ex. 5 | BCP-1 | (S1)-1 | 2891 | (S2)-1 | 2891 | — | — | A | A |
| Ex. 6 | BCP-1 | (S1)-1 | 4048 | (S2)-2 | 1735 | — | — | A | A |
| Ex. 7 | BCP-1 | (S1)-1 | 4048 | (S2)-3 | 1735 | — | — | A | A |
| Ex. 8 | BCP-1 | (S1)-1 | 4626 | (S2)-1 | 867 | (S3)-1 | 289 | A | A |
| Ex. 9 | BCP-1 | (S1)-1 | 4626 | (S2)-1 | 867 | (S3)-2 | 289 | A | A |
| Ex. 10 | BCP-1 | (S1)-1 | 4626 | (S2)-1 | 867 | (S3)-3 | 289 | A | A |
| Ex. 11 | BCP-1 | (S1)-1 | 4626 | (S2)-1 | 867 | (S3)-4 | 289 | A | A |
| Ex. 12 | BCP-1 | (S1)-1 | 4626 | (S2)-1 | 578 | — | — | A | A |
| | | | | (S2)-2 | 578 | | | | |
| Ex. 13 | BCP-1 | (S1)-1 | 4626 | (S2)-1 | 434 | (S3)-2 | 289 | A | A |
| | | | | (S2)-2 | 434 | | | | |
| Comp. | BCP-1 | (S1)-1 | 5782 | — | — | — | — | A | C |
| Ex. 1 | | | | | | | | | |
| Comp. | BCP-1 | — | — | (S2)-1 | 5782 | — | — | B | — |
| Ex. 2 | | | | | | | | | |
| Comp. | BCP-1 | (S1)-1 | 4048 | — | — | (S3)-1 | 1735 | A | C |
| Ex. 3 | | | | | | | | | |
| Comp. | BCP-1 | (S1)-1 | 4048 | — | — | (S3)-2 | 1735 | A | C |
| Ex. 4 | | | | | | | | | |
| Comp. | BCP-1 | (S1)-1 | 4048 | — | — | (S3)-3 | 1735 | B | — |
| Ex. 5 | | | | | | | | | |
| Comp. | BCP-1 | (S1)-1 | 4048 | — | — | (S3)-4 | 1735 | B | — |
| Ex. 6 | | | | | | | | | |

TABLE 2

| | (A) | (S1) | | (S2) | | (S3) | | Film-forming | |
|---|---|---|---|---|---|---|---|---|---|
| | Type | Type | Amount | Type | Amount | Type | Amount | performance | Defects |
| Ex. 14 | BCP-2 | (S1)-1 | 5204 | (S2)-1 | 578 | — | — | A | B |
| Ex. 15 | BCP-2 | (S1)-1 | 4626 | (S2)-1 | 1156 | — | — | A | A |
| Ex. 16 | BCP-2 | (S1)-1 | 4048 | (S2)-1 | 1735 | — | — | A | A |
| Ex. 17 | BCP-2 | (S1)-1 | 3469 | (S2)-1 | 2313 | — | — | A | A |
| Ex. 18 | BCP-2 | (S1)-1 | 2891 | (S2)-1 | 2891 | — | — | A | A |
| Ex. 19 | BCP-2 | (S1)-1 | 4048 | (S2)-2 | 1735 | — | — | A | A |
| Ex. 20 | BCP-2 | (S1)-1 | 4048 | (S2)-3 | 1735 | — | — | A | A |
| Comp. | BCP-2 | (S1)-1 | 5782 | — | — | — | — | A | C |
| Ex. 7 | | | | | | | | | |
| Comp. | BCP-2 | — | — | (S2)-1 | 5782 | — | — | B | — |
| Ex. 8 | | | | | | | | | |
| Comp. | BCP-2 | (S1)-1 | 4048 | — | — | (S3)-1 | 1735 | A | C |
| Ex. 9 | | | | | | | | | |
| Comp. | BCP-2 | (S1)-1 | 4048 | — | — | (S3)-2 | 1735 | A | C |
| Ex. 10 | | | | | | | | | |
| Comp. | BCP-2 | (S1)-1 | 4048 | — | — | (S3)-3 | 1735 | B | — |
| Ex. 11 | | | | | | | | | |
| Comp. | BCP-2 | (S1)-1 | 4048 | — | — | (S3)-4 | 1735 | B | — |
| Ex. 12 | | | | | | | | | |

TABLE 3

| | (A) | (S1) | | (S2) | | (S3) | | Film-forming | |
|---|---|---|---|---|---|---|---|---|---|
| | Type | Type | Amount | Type | Amount | Type | Amount | performance | Defects |
| Ex. 21 | BCP-3 | (S1)-1 | 5204 | (S2)-1 | 578 | — | — | A | B |
| Ex. 22 | BCP-3 | (S1)-1 | 4626 | (S2)-1 | 1156 | — | — | A | A |
| Ex. 23 | BCP-3 | (S1)-1 | 4048 | (S2)-1 | 1735 | — | — | A | A |
| Ex. 24 | BCP-3 | (S1)-1 | 3469 | (S2)-1 | 2313 | — | — | A | A |
| Ex. 25 | BCP-3 | (S1)-1 | 2891 | (S2)-1 | 2891 | — | — | A | A |
| Ex. 26 | BCP-3 | (S1)-1 | 4048 | (S2)-2 | 1735 | — | — | A | A |
| Ex. 27 | BCP-3 | (S1)-1 | 4048 | (S2)-3 | 1735 | — | — | A | A |
| Comp. | BCP-3 | (S1)-1 | 5782 | — | — | — | — | A | C |
| Ex. 13 | | | | | | | | | |
| Comp. | BCP-3 | — | — | (S2)-1 | 5782 | — | — | B | — |
| Ex. 14 | | | | | | | | | |
| Comp. | BCP-3 | (S1)-1 | 4048 | — | — | (S3)-1 | 1735 | A | C |
| Ex. 15 | | | | | | | | | |
| Comp. | BCP-3 | (S1)-1 | 4048 | — | — | (S3)-2 | 1735 | A | C |
| Ex. 16 | | | | | | | | | |
| Comp. | BCP-3 | (S1)-1 | 4048 | — | — | (S3)-3 | 1735 | B | — |
| Ex. 17 | | | | | | | | | |
| Comp. | BCP-3 | (S1)-1 | 4048 | — | — | (S3)-4 | 1735 | B | — |
| Ex. 18 | | | | | | | | | |

Tables 1 to 3 show that a uniform film was successfully formed when using the compositions of the examples containing, as the organic solvent(S), propylene glycol monomethyl ether acetate (S1) and a solvent (S2) having an ester group and a boiling point at atmospheric pressure of 225° C. or more and 275° C. or less each successfully formed, and that the formation of defected in the phase-separated film was suppressed when forming a thick phase-separated film. On the other hand, when the compositions of the comparative examples containing only either propylene glycol monomethyl ether acetate (S1) or solvent (S2) as the organic solvent(S) was used, the film formation was uneven or the number of defects was large.

What is claimed is:

1. A resin composition for forming a phase-separated structure comprising:
a block copolymer (A); and
an organic solvent(S),
wherein the organic solvent(S) comprises propylene glycol monomethyl ether acetate (S1) and a solvent (S2) having an ester group and a boiling point at atmospheric pressure of 225° C. or more and 275° C. or less.

2. The resin composition for forming a phase-separated structure according to claim 1, wherein a ratio of the mass of the solvent (S2) to total mass of the propylene glycol monomethyl ether acetate (S1) and the solvent (S2) is 5% by mass or more and 60% by mass or less.

3. The resin composition for forming a phase-separated structure according to claim 1, wherein a ratio of a sum of mass of the propylene glycol monomethyl ether acetate (S1) and mass of the solvent (S2) to total mass of the solvent(S) is 90% by mass or more.

4. The resin composition for forming a phase-separated structure according to claim 1, wherein the solvent (S2) is a compound represented by Formula (s2-1): 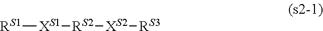
wherein R^{S1} is a hydrogen atom or an optionally substituted alkyl group, R^{S1} is a single bond or an optionally substituted alkylene group, R^{S1} is an optionally substituted alkyl group, X^{S1} is a single bond or an ester group, and X^{S1} is an ester group.

5. The resin composition for forming a phase-separated structure according to claim 1,
wherein the block copolymer (A) comprises at least one selected from the group consisting of a block copolymer (A1), a block copolymer (A2), and a block copolymer (A3),
the block copolymer (A1) comprises a block (A1-1) and a block (A1-2), wherein the block (A1-1) comprises a polymer having a repeating structure of a structural unit represented by Formula (a1) below, and the block (A1-2) comprises a polymer having a repeating structure of a structural unit represented by Formula (a3) below,
wherein the block copolymer (A2) comprises a block (A2-1) and a block (A2-2), the block (A2-1) comprises a polymer having a repeating structure of a structural unit represented by Formula (a1) below, and the block (A2-2) comprises a random copolymer having a structure in which a structural unit represented by Formula (a2) below and a structural unit represented by Formula (a3) below are randomly arranged,
wherein the block copolymer (A3) comprises a block (A3-1), a block (A3-2), and a block (A3-3), the block (A3-1) comprises a polymer having a repeating structure of a structural unit represented by Formula (a1) below, the block (A3-2) comprises a polymer having a repeating structure of a structural unit represented by Formula (a2) below, and the block (A3-3) comprises a polymer having a repeating structure of a structural unit represented by Formula (a3) below, 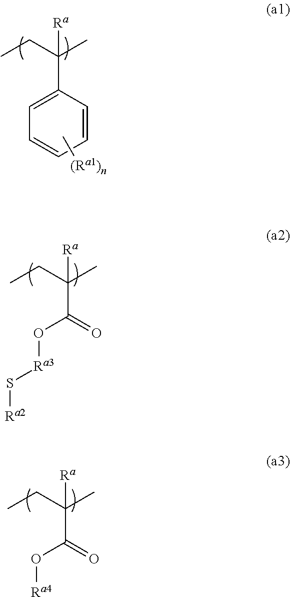
wherein in Formula (a1), R^{a1} is an optionally substituted alkyl group, and n is an integer of 0 or more and 5 or less,
in Formula (a2), R^{a2} is an alkyl group optionally substituted with a silyl group, a fluorine atom, a carboxy group, an amino group, a hydroxy group, or a phosphate group, and R^{a3} is an alkylene group optionally substituted with a hydroxy group,
in Formula (a3), R^{a4} is an optionally substituted alkyl group, and
in Formulas (a1), (a2), and (a3), R^{a} is a hydrogen atom or a methyl group.

6. A method of producing a structure having a phase-separated structure, the method comprising:
applying the resin composition for forming a phase-separated structure according to claim 1 on a support to form a layer comprising a block copolymer; and
phase separating the layer comprising the block copolymer.
